(19) United States
(12) Patent Application Publication
(10) Pub. No.: US 2008/0057702 A1
(43) Pub. Date: Mar. 6, 2008

(54) MEHTOD OF MANUFACTURING SEMICONDUCTOR DEVICE

(75) Inventors: Hiroyuki Fukumizu, Kawasaki-shi (JP); Takeshi Yamauchi, Yokohama-shi (JP)

Correspondence Address: PEARNE & GORDON LLP, 1801 EAST 9TH STREET, SUITE 1200, CLEVELAND, OH, 44114-3108, US

(73) Assignee: KABUSHIKI KAISHA TOSHIBA, Tokyo (JP)

(21) Appl. No.: 11/684,846

(22) Filed: Mar. 12, 2007

(30) Foreign Application Priority Data
Aug. 30, 2006 (JP) 2006-233771

(51) Int. Cl. H01L 21/4763

(52) U.S. Cl. 438/624; 257/E21.495

(57) ABSTRACT

A method of manufacturing a semiconductor device includes forming an inter-layer insulating film on a silicon substrate, drying etching the inter-layer insulating film with an etching gas containing halogen using a mask of an organic material, forming a contact hole at a predetermined position on the inter-layer insulating film, separating and removing the mask of the organic material, coating a resist containing OH or H on the inter-layer insulating film including the contact hole followed by ashing with oxygen plasma, and burying a conductive material in the contact hole.

### CROSS-REFERENCE TO RELATED APPLICATIONS

This application is based upon and claims the benefit of priority from prior Japanese Patent Application No. 2006-233771, filed Aug. 30, 2006, the entire contents of which are incorporated herein by reference.

### BACKGROUND OF THE INVENTION

1. Field of the Invention

The present invention relates to a method of manufacturing a semiconductor device, and in particular to a post-process for removing halide remaining on the bottom surface of the contact hole after dry etching.

2. Description of the Related Art

A method of manufacturing a semiconductor device in which an insulating film formed on a silicon substrate is dry etched using a mask of an organic material thereby to form a contact hole is widely used. Especially, the reactive ion etching (RIE), for example, is conducted in the plasma as a microprocessing technique. In this process, the etching gas containing halogen such as fluorine, chlorine or bromine is converted into plasma and the chemical reaction of a radical (active gas) of halogen group generated in the plasma is utilized.

The aspect ratio of the contact hole connecting a diffusion layer and a wiring layer is ever on the increase, and has recently exceeded 5. In this situation demanding a high aspect ratio, the contact hole processing requires a large etching selection ratio between a resist mask and an inter-layer insulating film.

Specifically, the process with high ion energy is required using the fluorocarbon gas high in C/F ratio such as C₄F₈, C₅F₈ or C₄F₆ as an etching gas for dry etching.

As a result, the fluoride (F) such as fluorocarbon polymer is unavoidably deposited on the resist surface and the peripheral wall and the bottom surface of the contact hole. The fluoride should be disposed of in the ashing process or the cleaning process after dry etching. After that, the contact hole is covered with a barrier metal such as titanium (Ti) or titanium nitride (TiN) and buried with a conductive material made of tungsten (W) or polysilicon.

In the case where the fluoride remains, especially, on the bottom surface after processing the contact hole, however, the contact resistance would be increased in the boundary between the conductive material and the silicon substrate constituting a semiconductor substrate, and the connection (ohmic contact) is instabilized. Especially, for the hole size of not larger than 10 nm, the effect of the resistance increase due to the boundary impurities cannot be ignored.

Jpn. Pat. Appln. KOKAI Publication Nos. 11-233453 and 2002-124485 disclose a method of removing the fluoride remaining on the bottom surface of the contact hole due to the etching byproducts to suppress the resistance increase caused by the boundary impurities.

According to the technique described in Jpn. Pat. Appln. KOKAI Publication No. 11-233453, a contact hole is formed on an inter-layer insulating film on a semiconductor substrate, and after depositing a titanium film on the diffusion layer and the inter-layer insulating film, the semiconductor substrate is heated to a high temperature in the argon atmosphere thereby to form a titanium silicide film on the surface of the diffusion layer. After that, a titanium nitride layer is deposited and a tungsten film is buried in the contact hole thereby to form a wiring layer.

With the aforementioned technique, after forming a titanium silicide film by the high-temperature heat treatment, a titanium nitride layer is deposited using the chemical vapor deposition (CVD) to prevent the titanium silicide film formation from being hampered or prevent the defect generation in the titanium nitride film. It is difficult, however, to completely remove the fluoride on the bottom surface of the contact hole by heat treatment, and the semiconductor substrate and the inter-layer insulating film may be subjected to a thermally adverse effect.

The technique disclosed in Jpn. Pat. Appln. KOKAI Publication No. 2002-124485, on the other hand, includes a step of processing, with argon plasma in a processing chamber, the contact area or the diffusion layer having a concave bottom surface formed on the semiconductor substrate and removing the insulating film existing on the surface of the contact area or the diffusion layer, as the case may be. The argon plasma process is executed by applying high-frequency power and thereby exciting the argon plasma so that the absolute value of the self-bias voltage applied to the semiconductor substrate may not be lower than 100 V.

Specifically, according to the technique described above, ionized metal particles enter the semiconductor substrate with a directivity, and removes a natural oxide film on the bottom surface of the contact hole formed to a high aspect ratio. Nevertheless, the ionized metal particles are liable to scrape off the peripheral portion of the opening of the contact hole of the inter-layer insulating film, thereby deforming the contact hole and enlarging the opening diameter resulting in a deteriorated reliability.

### BRIEF SUMMARY OF THE INVENTION

According to an aspect of the invention, there is provided a method of manufacturing a semiconductor device according to the present invention comprises the steps of: forming a conductive area at a predetermined position on a semiconductor substrate; forming an insulating film on the semiconductor substrate; forming a contact hole electrically connected to the conductive area, at a predetermined part of the insulating film by dry etching with an etching gas containing halogen using a mask; forming a film of an organic material containing OH or H on the inner surface of the contact hole; ashing the organic material film containing OH or H with oxygen plasma; and burying a conductive material in the contact hole.

According to another aspect of the invention, there is provided a method of manufacturing a semiconductor device according to the present invention comprises the steps of: forming a conductive area at a predetermined position on a semiconductor substrate; forming an insulating film on the semiconductor substrate; forming a contact hole electrically connected to the conductive area, at a predetermined part of the insulating film by dry etching with an etching gas containing halogen using a mask; forming a film of an organic material containing OH or H on the inner surface of the contact hole; ashing the organic material film containing OH or H with oxygen plasma; executing selected one of a wet etching process with an aqueous solution of dilute hydrofluoric acid and a back sputtering process with argon (Ar) in the contact hole after the ashing process; and burying a conductive material in the contact hole.

### BRIEF DESCRIPTION OF THE SEVERAL VIEWS OF THE DRAWING

The accompanying drawings, which are incorporated in and constitute a part of the specification, illustrate embodiments of the invention.

FIGS. 1A to 1C are sectional views of the essential parts showing a semiconductor manufacturing step according to a first embodiment of the invention;

FIGS. 2A to 2D are sectional views of the essential parts showing the semiconductor manufacturing step according to the same embodiment;

FIG. 3 is a diagram showing the result of analysis of the surface condition with XS before and after the process of cleaning the contact hole according to the same embodiment; and

FIGS. 4A and 4B are sectional views of the essential parts showing the semiconductor manufacturing step according to a second embodiment of the invention.

### DETAILED DESCRIPTION OF THE INVENTION

A method of manufacturing a semiconductor device according to an embodiment of the invention is explained below with reference to the drawings.

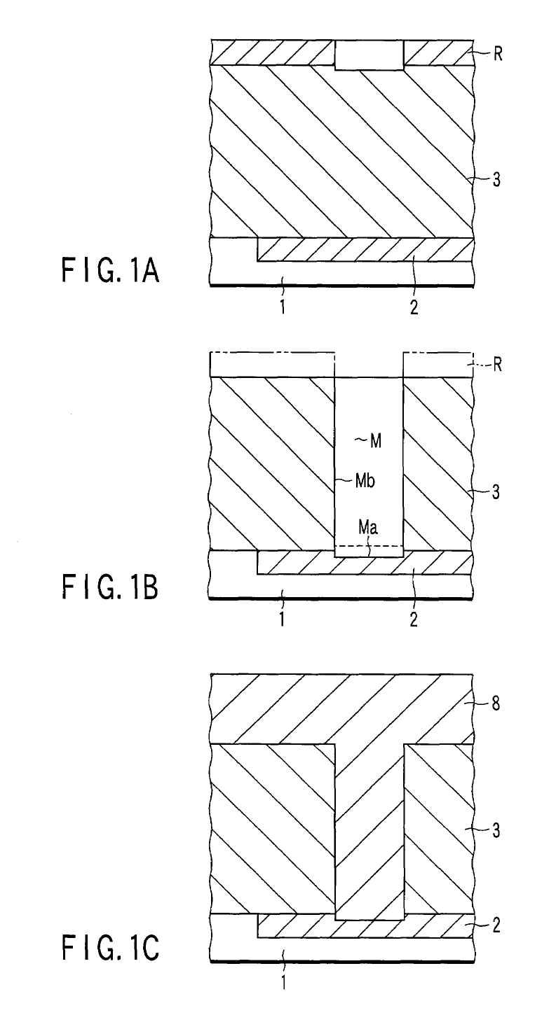

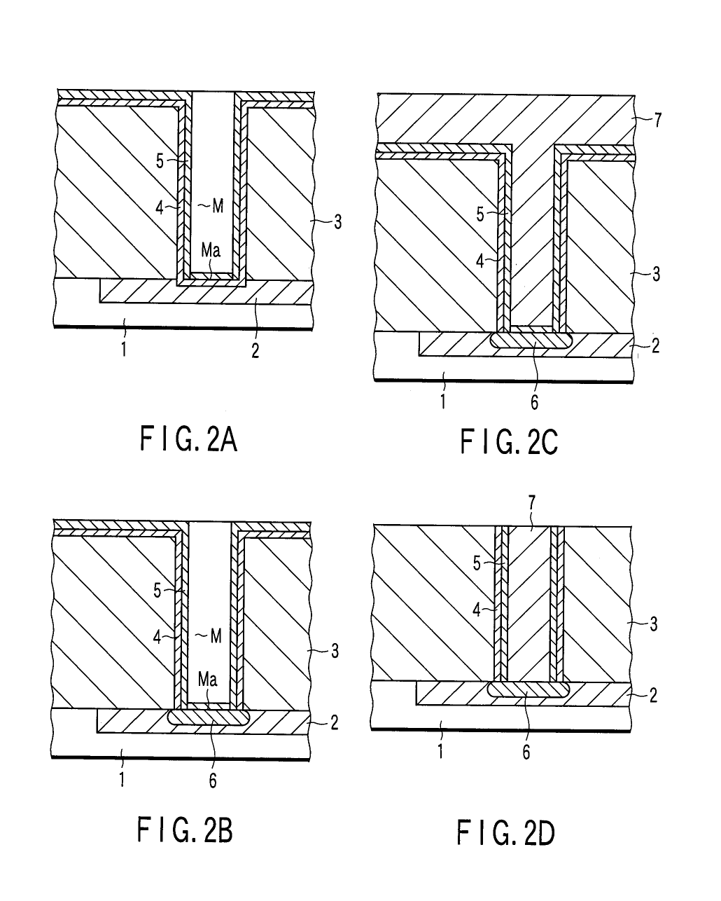

FIGS. 1A to 1C, 2A to 2D are partial sectional views of a semiconductor device in main step according to a first embodiment.

As shown in FIG. 1A, a diffusion layer 2 making up a source electrode and a drain electrode of a MOS transistor is formed on a selected part of a silicon (Si) substrate 1 serving as a semiconductor substrate. In the process, the well-known lithography and the ion implantation technique can be used to form the diffusion layer 2.

Next, an inter-layer insulating film 3 is formed on the silicon substrate 1 and the diffusion layer 2 by CVD. The inter-layer insulating film 3 is formed of silicon oxide such as a fusible BPSG (boron phosphorous silicate glass) film.

Further, the surface of the inter-layer insulating film 3 is coated and covered with a resist R constituting an example of a mask of an organic material. Then, a pattern is formed by lithography on the part of the resist R to be formed with a gate electrode.

As shown in FIG. 1B, with the patterned resist R as a mask, a contact hole M is formed on the inter-layer insulating film 3 using the dry etching technique. In this case, the reactive ion etching (RIE) process is executed using a gas of fluorine group (CFₓ) as an etching gas. The exemplary etching gas includes CF₄ alone or CF₄+O₂ or CF₄+H₂.

In the process, SiFₓ is generated by the reaction between the etching gas (CF₄) and the silicon substrate 1 exposed to the bottom Ma of the contact hole M. Also, fluorocarbon polymer (CFₓ) is deposited on the peripheral wall Mb and the bottom Ma of the contact hole M by the reaction between the etching gas (CF₄) and the resist R.

Next, the ashing process is executed to separate the resist R with the O radical generated by the O₂ plasma. At the same time, CFₓ deposited on the peripheral wall Mb and the bottom Ma of the contact hole M is removed by the O radical, while C is removed as CO or CO₂. Nevertheless, SiFₓ remains without being removed.

After that, the surface of the inter-layer insulating film 3 is cleaned using the mixture solution of sulfuric acid and hydrogen peroxide. As a result, the resist R and CFₓ which could not be removed by the ashing process are removed. Nevertheless, SiFₓ still remains on the surface of the bottom Ma of the contact hole M and is difficult to remove.

The remaining SiFₓ may be removed by oxidization in the wet etching process using the aqueous solution of dilute hydrofluoric acid on the surface of the inter-layer insulating film 3. At the same time, however, the inter-layer insulating film 3 would also be retreated by etching and the diameter of the contact hole M is enlarged. Therefore, the wet etching process cannot be used for removing SiFₓ.

In view of this, the process for removing the halide SiFₓ remaining on the bottom Ma of the contact hole M is inserted. Specifically, as shown in FIG. 1C, a resist 8 containing hydrogen oxide (OH) or hydrogen (H) is coated over the entire surface to such an extent as to bury the contact hole M, and under this condition, the oxygen plasma ashing process is executed to remove the resist 8 with the O radical generated by the O₂ plasma.

In the process, the resist 8 may be any form of film of an organic material containing OH or H such as Novolak (trade name of JSR: PER I x 370 G) resin film.

In the process shown in FIG. 1C, application of the resist 8 causes the halide SiFₓ to react directly with the component (OH or H) of the resist 8, and during the ashing process using the oxygen plasma, F, for example, is volatilized off to HF by hydrogen oxide (OH) or hydrogen (H) volatilized from the resist 8.

At the same time, Si is bonded (oxidized) with the oxygen (O) component and remains as a SiOₓ film. By the wet etching process for coating the aqueous solution of dilute hydrofluoric acid, however, the SiOₓ film is etched off, and the surface of the bottom Ma of the contact hole M is cleaned. For removing the SiOₓ film, the argon (Ar) back sputtering may be used instead of chemical processing with hydrofluoric acid.

Next, as shown in FIG. 2A, the peripheral wall Mb and the bottom Ma of the contact hole M are formed with a titanium nitride (TiN) film 4 and a titanium (Ti) film 5 using the CVD or sputtering.

After that, the silicon substrate 1 processed as described above is subjected to heat treatment in the inert gas atmosphere such as argon (Ar) gas. During this heat treatment process, as shown in FIG. 2B, the component (Si) of the silicon substrate 1 reacts with the titanium film 5 and a titanium silicide (TiSₓ) layer 6 is formed.

As a result, the SiFₓ film and the SiOₓ film in the boundary are removed, and the contact resistance for electric conduction is reduced. In the case where a great amount of impurities exist in the boundary between the silicon component (Si) of the silicon substrate 1 and the titanium (Ti), however, the silicide reaction would be hampered, and therefore the contact resistance is not reduced considerably. Especially, once the diameter of the contact hole M becomes very small, the resistance is conspicuously increased by the impurities.

Next, as shown in FIG. 2C, a tungsten (W) film 7 is formed on the titanium nitride film 4 in such a manner as to bury the contact hole M by the CVD process using the WF₆ gas.

Then, as shown in FIG. 2D, the tungsten (W) film 7, the titanium film 5 and the titanium nitride film 4 on the surface of the inter-layer insulating film 3 are removed using the chemical mechanical polishing (CMP). As a result, the tungsten (W) film 7 is buried and a metal plug 9 is formed in the contact hole M.

Finally, though not specifically shown, a wiring layer conducting with the metal plug 9 is formed on the metal plug 9. In the process, an aluminum alloy film is deposited on the inter-layer insulating film 3 and the tungsten film 7 and processed into a predetermined shape by lithography and dry etching thereby to form a wiring layer.

According to this embodiment, as explained with reference to FIG. 1B, the contact hole M is formed by dry etching the inter-layer insulating film 3, and after separating the resist R constituting the mask of an organic material, the process is inserted to remove the halide SiFₓ remaining on the bottom Ma of the contact hole M.

Specifically, as shown in FIG. 1C, the resist (organic material) 8 containing hydrogen oxide (OH) or hydrogen (H) is coated and covered over the entire surface in such a manner as to bury the contact hole M. Then, the oxygen plasma ashing process is executed to remove the resist 8 with the O radical generated by the O₂ plasma.

As described above, according to this embodiment, the mask R of an organic material is separated by the ashing process after dry etching, and the resist 8 containing OH or H is coated on the inter-layer insulating film 3 cleaned. Under this condition, the ashing process is executed by the oxygen plasma, and further, the silicon oxide film (SiO₂) is wet etched thereby to remove all the fluoride (F) deposited after dry etching.

Let us add that an organic material such as resist containing OH or O is coated on the inter-layer insulating film 3 on which the halide remains, and the ashing process is executed with the oxygen plasma. Thus, OH or H generated during ashing reacts with halogen and volatilizes. Thus, SiFₓ is removed, and Si is oxidized. Further, the silicon oxide is removed by wet etching or Ar back sputtering thereby to suppress the increase in boundary resistance.

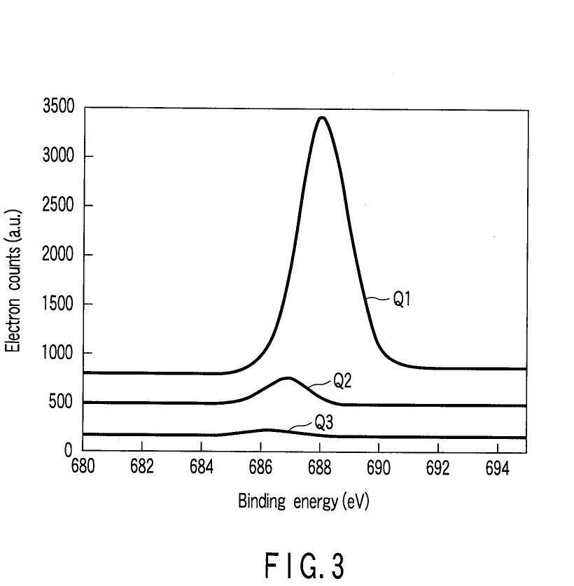

FIG. 3 shows the result of analyzing the surface condition by XPS (X-ray photo-electron spectroscopy) after etching and resist separation. The abscissa represents the binding energy, and the ordinate represents electron counts.

The pattern measured for the present purpose includes not the bottom of the contact hole but the bottom of a hole of an open 1-mm square pattern. FIG. 3 shows the spectrum of F1s.

As shown by the analysis result Q1 of FIG. 3, the inter-layer insulating film 3 is masked by the resist R of an organic material, and the contact hole M is formed by dry etching using an etching gas containing halogen, after which the peak of F1s before separating the resist R is detected with the binding energy of about 688 eV. This peak is generally considered attributable to C₄F or CFₓ.

As shown by the analysis result Q2 of FIG. 3, the peak of F1s after forming the contact hole M by etching and separating the resist R is detected with the binding energy in the neighborhood of 687 eV. This peak, unlike the peak for C₄F or CFₓ, is considered attributable to SiF. In this way, it is understood that the etching residue (byproducts) are not removed from the surface of the inter-layer insulating film 3 including the contact hole M.

The analysis result Q3 of FIG. 3 also shows that no F1s peak is observed after the process of coating the resist 8 on the inter-layer insulating film 3 including the contact hole M and the ashing process with O₂ plasma.

Specifically, these analysis results indicate that the CFₓ and SiFₓ deposits are positively removed by the coating of the resist 8 using the Novolak resin film and the ashing process using the oxygen plasma.

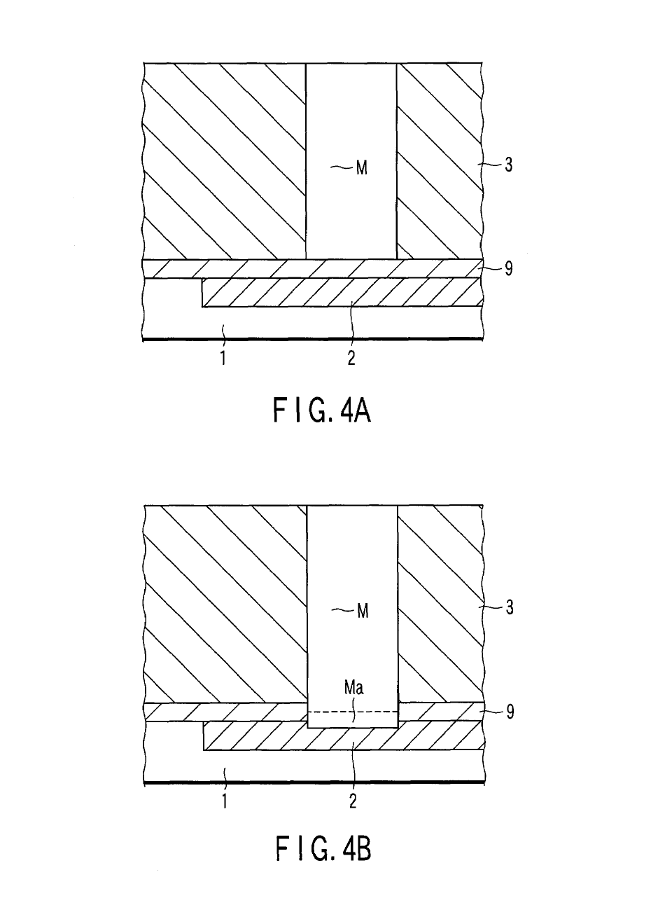

Next, a second embodiment of the invention will be explained with reference to FIGS. 4A and 4B.

As shown in FIG. 4A, the inter-layer insulating film according to the first embodiment described above is replaced with a configuration including a silicon oxide film 10 and a silicon nitride film 11. Specifically, the silicon nitride film 11 is formed as a base of the silicon oxide film 10.

In order to form a contact hole M in the silicon oxide film 10, the silicon oxide film 10 is subjected to dry etching with an etching gas containing the halogen gas using a mask of an organic material constituting a resist.

Since silicon nitride (TiN) has a high selection ratio with respect to the silicon oxide film 10, the dry etching process suppresses the reduction in the silicon nitride film 11. In other words, the silicon nitride film 11 can be rendered to function as an etching stopper layer.

As shown in FIG. 4B, the resist is separated subsequently, and with the silicon oxide film 10 as a mask, the silicon nitride film 11 is subjected to dry etching. An etching gas containing halogen gas is used also in this case.

During the process of forming the contact hole M in this way, the silicon substrate 1 or, especially, the diffusion layer 2 is prevented from being excessively etched. After cleaning the surface of the silicon oxide film 10 by ashing and wet etching, the surface of the silicon oxide film 10 including the contact hole M is covered with a resist constituting a film of an organic material containing OH or H. Further, the ashing process is executed with oxygen plasma thereby to remove SiFₓ remaining on the surface of the bottom Ma of the contact hole M.

As described above, even in the case where the inter-layer insulating film described in the first embodiment above is replaced with a configuration including the silicon oxide film 10 and the silicon nitride film 11, it is possible to remove SiFₓ covering the bottom surface of the contact hole M and suppress the increase in the boundary resistance.

In the aforementioned process, the silicon oxide film 10 and the silicon nitride film 11 may be opened continuously using the resist mask, followed by separation and removal of the resist mask.

This invention is not limited to the embodiments described above as they are, but in embodying the invention, the component elements thereof can be modified specifically without departing from the spirit and scope of the invention. Also, various inventions can be achieved by appropriate combinations of the plurality of the component elements disclosed in the embodiments.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A method of manufacturing a semiconductor device, comprising:
forming a conductive area at a predetermined position on a semiconductor substrate;
forming an insulating film on the semiconductor substrate;
forming a contact hole electrically connected to the conductive area, at a predetermined part of the insulating film by dry etching with an etching gas containing halogen using a mask;
forming a film of an organic material containing OH or H on the inner surface of the contact hole;
ashing the organic material film containing OH or H with oxygen plasma; and
burying a conductive material in the contact hole.

2. The method of manufacturing a semiconductor device according to claim 1,
wherein the mask is formed of an organic material, and after ashing the mask using oxygen plasma, a film of an organic material containing OH or H is formed on the inner surface of the contact hole.

3. The method of manufacturing a semiconductor device according to claim 1,
wherein after forming the contact hole, a fluoride is formed on the inner surface of the contact hole.

4. The method of manufacturing a semiconductor device according to claim 1,
wherein the insulating film is composed of a silicon nitride film and a silicon oxide film formed on the silicon nitride film.

5. A method of manufacturing a semiconductor device, comprising:
forming a conductive area at a predetermined position on a semiconductor substrate;
forming an insulating film on the semiconductor substrate;
forming a contact hole electrically connected to the conductive area, at a predetermined part of the insulating film by dry etching with an etching gas containing halogen using a mask;
forming a film of an organic material containing OH or H on the inner surface of the contact hole;
ashing the organic material film containing OH or H with oxygen plasma;
executing selected one of a wet etching process with an aqueous solution of dilute hydrofluoric acid and a back sputtering process with argon (Ar) in the contact hole after the ashing process; and
burying a conductive material in the contact hole.

6. The method of manufacturing a semiconductor device according to claim 5,
wherein the mask is formed of an organic material, and after ashing the mask using oxygen plasma, a film of an organic material containing OH or H is formed on the inner surface of the contact hole.

7. The method of manufacturing a semiconductor device according to claim 5,
wherein after forming the contact hole, a fluoride is formed on the inner surface of the contact hole.

8. The method of manufacturing a semiconductor device according to claim 5,
wherein the insulating film is composed of a silicon nitride film and a silicon oxide film formed on the silicon nitride film.
